(19) United States
(12) Patent Application Publication
(10) Pub. No.: US 2005/0062011 A1
(43) Pub. Date: Mar. 24, 2005

(54) FERROELECTRIC SINGLE CRYSTAL RESONATOR AND METHODS FOR PREPARATION AND USE THEREOF

(75) Inventors: Ilia Natanovich Geifman, Skokie, IL (US); Iryna Sergeevna Golovina, Kiev (UA)

Correspondence Address: LEONID KHODOR, 4920 BRAINARD ROAD, ORANGE, OH, 44022, US

(73) Assignee: ELECTROPLATED METAL SOLUTIONS, INC., Elk Grove Village, IL (US)

(21) Appl. No.: 10/605,251

(22) Filed: Sep. 18, 2003

(51) Int. Cl. C30B 29/30; C04B 35/00; C04B 35/46; C04B 35/48; C04B 35/49

(52) U.S. Cl. 252/62; 501/134; 252/62.9 R; 117/948

(57) ABSTRACT

A ferroelectric single crystal consisting essentially of potassium tantalate and the alkali metal substituting from about 1% to 3% of potassium or a group (V) metal substituting in part for tantalum, having cubic form of perovskite crystalline structure, and essentially free of impurities and defects is produced by growing it from a melt of a potassium precursor, a tantalum oxide and the alkali metal precursor or a group (V) metal oxide. A microwave resonator comprising the single crystal that is useful in a number of RF and EPR applications, an EPR spectrometer comprising a ferroelectric single crystal resonator, a rectangular cavity, a permanent magnet with planar poles, and a radio frequency AC generator with two connecting wires, and a NMR spectrometer comprising a magnet, means for transmitting a radio frequency magnetic pulse and detecting NMR signal, and a ferroelectric single crystal resonator are also disclosed.

### BACKGROUND OF INVENTION

This invention generally relates to the field of fabrication and use of ferroelectric single crystals resonators, in particular to single crystal microwave resonators comprising the potassium tantalate and methods for preparation and use thereof. This invention as well relates to the field of magnetic resonance instruments, specifically to EPR and NMR spectrometers.

Ferroelectric crystals are materials, characterized by high dielectric constant (ε). Certain binary metal oxides, particularly oxides of combinations of alkali with group (V) metals and of alkaline earth with group (IV) metals are ferroelectrics. A potassium tantalate crystal is unique among ferroelectrics because it combines, in spite of the lowering temperature, the rising considerably isotropic dielectric constant, which reaches 4000 at approximately 4.2° K with decreasing dielectric losses. These features provide for resonators of high quality (Q) even under super low temperature conditions. The potassium tantalate single crystal is the promising material for radio frequency and microwave resonators and, as a result, for Electron Paramagnetic Resonance (EPR) and Nuclear Magnetic Resonance (NMR) applications including spectroscopy and imaging (MRI).

It has been known that ferroelectrics in general and especially a potassium tantalate single crystal can improve an EPR spectrometer performance when used both either as an insert (secondary resonator) in existing spectrometers or as a primary resonator. The later provides for a possibility of decreasing size and cost of spectrometers. However, a single crystal of the nominally pure potassium tantalate most often shows EPR spectra of iron (Fe³⁺), which is present in the crystal as an uncontrolled impurity. Therefore, when used as a resonator, the crystal carries own background EPR signal that overlaps sample spectra. Furthermore, other possible impurities and structural defects further limit usefulness of the crystal.

An EPR resonator made of single crystal potassium tantalate doped with lithium (Li), which replaces 0.01 0.1% of potassium disclosed in UA Pat. No. 40178A. The crystal characterized by absence of the background signal, decreasing irregularities, and stronger crystal lattice. Nonetheless, the resonator is of limited use because, at low temperatures, the crystal walls surrounding a central hole for a sample are becoming too thin to sustain stresses of a microwave field. Alternatively, NMR applications, due to lower frequency range, require radically greater size of the resonator, its ε, or both.

Traditionally, variations of Czochralski method is used for growing sizable ferroelectric single crystals in general and potassium tantalate single crystals in particular. Different means are employed for achieving desired crystal parameters. Particularly, controlling melt component relative quantities, temperature, temperature gradient, flow direction and intensity; growing in the air, special atmosphere, or vacuum; manipulating seed lifting speed, rotational direction and velocity have been known in the art.

However, almost each chemical composition requires own set of conditions for growing single crystals of satisfactory quality. Finding right conditions for growing a particular crystal remains as much an art as a science. Thus, there remains an unresolved need in the art for an improved method of producing ferroelectric potassium tantalate single crystal having cubic form of perovskite crystalline structure and is essentially free of impurities and defects.

Electron Paramagnetic Resonance (EPR) is widely applied in physics, chemistry, medicine and biology. Earlier EPR was used mostly to study samples doped with paramagnetic ions. Since dopant impurities affect physical properties of substances, it is more significant to study nominally pure samples. Therefore it becomes extremely important to increase the sensitivity of EPR spectrometers. It is most significant for studying natural materials with low concentration of paramagnetic centers.

One of the simplest techniques of increasing signal-to-noise (S/N) ratio is to place the dielectric material inside a resonator. Thus, when a quartz plate is inserted nearby the sample, the S/N ratio is increased 4.5 times. Increasing EPR signal intensity can also be obtained by using ferroelectric material as a microwave resonator. For instance, rutile (TiO₂) rectangular resonator has been used to increase Fe³⁺ EPR spectrum. Dielectric resonators fabricated from TiO₂ and SrTiO₃ (these materials have anisotropic permittivity) were used only for increasing the EPR signal intensities of paramagnetic centers inside themselves.

Most EPR spectrometers have generally included a high Q resonant metal cavity. A high Q cavity requires a high ratio of the cavity volume to the cavity wall surface, which in turn necessitates a relatively large volume of polarizing magnetic field, thereby requiring a large magnet weighing 1000 kg or more. Heretofore, these spectrometers have been designed to obtain a flexible instrument of high sensitivity for a broad variety of samples in a wide variety of applications. This objective has resulted in research-type equipment, which is generally considered very expensive.

Influence of a ferroelectric object (resonator) inserted into a standard cavity on a continuous wave (CW) EPR signal and on Pulse EPR echo intensities has been stud (see, I. N. Geifman, I. S. Golovina, V. I. Kofman, and E. R. Zusmanov, Ferroelectrics, Vol.234 (1-4), pp.81-88 (1999)). The resonating structure enabled to investigate any material. Ferroelectric KTaO₃ resonators described in this work increased signal-to-noise ratio 10 times at room temperature for rectangular resonator in CW EPR experiments and enabled to reduce microwave power by factor of 50 at 50 K in electron spin echo (ESE) experiment. The resonator advantages are that not only ferroelectric but also any material can be monitored and studied, it has isotropic dielectric constant, and it has low dielectric losses. Although ferroelectric resonator has much smaller dimensions in comparison with dielectric one, can be applied for liquid and solid samples, and increases the sensitivity of the spectrometer, it is still the secondary resonator that works only within the standard cavity.

EPR spectrometer, disclosed in U.S. Pat. No. 3,931,569, designed from the point of view of arriving at a high sensitivity instrument for examining aqueous samples or other liquid samples of relatively high dielectric loss at room temperature. As is well known, the polarizing magnetic field for electron paramagnetic resonance is parallel to a cavity dimension that corresponds to the zero index, and the magnitude of this cavity dimension does not affect the resonant frequency of the cavity. The cavity dimension corresponding to the zero index is made small, of the order of an optimum capillary sample tube outer diameter, i.e., 2 mm if the diameter is 1 mm, for apparatus designed to operate at 10 GHz. It has been found that the sensitivity of the spectrometer is as high as that obtained from high Q cavities of conventional design where the dimension corresponding to the zero index is typically 15 mm at 10 GHz. The design is directed particularly to EPR spectrometers utilizing rectangular TE₁₀₂ or cylindrical TM₁₁₀ modes and provides low-cost apparatus for a very restricted range of applications. The low Q resonant cavity can be applied to analyze aqueous samples only.

Although NMR devices, due to lower relative to EPR frequency range, have a radio frequency (RF) coil instead of the cavity as the resonator, fundamental dependencies remain between the resonator size and the device capabilities, complexity, size, and cost. The dependencies equally affect NMR spectrometers, MASERs, probes and, generally, any device with the RF coil.

NMR spectrometers have now become very complex instruments capable of performing sophisticated experiments. However, the really important parts of the spectrometer are not that complex to understand in outline. Broken down to its simplest form, the spectrometer consists of an intense, homogeneous, and stable magnetic field; a “probe”, which enables RF coils to be placed close to a sample; a RF transmitter capable of delivering short pulses; a receiver to amplify the NMR signals; a digitizer to convert the NMR signals into a form, which can be stored in computer memory; a “pulse programmer” to produce precisely timed pulses and delays; and a computer to control everything and to process the data.

Current invention relates to the probe and, consequently, to the magnetic field. As the static magnetic field generating magnet constituting the NMR spectrometer, a resistive magnet of 0.5 to 2.2 T, and a superconducting magnet of 0.5 to 18.8 T have been used, and a permanent magnet is also used in some cases. Modern NMR spectrometers use persistent superconducting magnets to generate the B₀ field. Basically such a magnet consists of a coil of wire through which a current passes, thereby generating a magnetic field. The wire is of a special construction such that at low temperatures (less than 6 K, typically) the resistance goes to zero that is the wire is superconducting. Thus, once the current is set running in the coil it will persist for ever, thereby generating a magnetic field without the need for further electrical power. Superconducting magnets tend to be very stable and so are very useful for NMR. To maintain the wire in its superconducting state the coil is immersed in a bath of liquid helium. Surrounding this is a “heat shield” kept at 77 K by contact with a bath of liquid nitrogen; this reduces the amount of expensive liquid helium, which boils off due to heat flowing in from the surroundings. The whole assembly is constructed in a vacuum flask so as to further reduce the heat flow.

There is a room temperature sample region accessible to the outside world. The region has to be engineered as part of the design of the magnet and, usually, it takes the form of a vertical tube passing through the magnet (called the bore tube of the magnet); the magnetic field is in the direction of this tube.

The lines in NMR spectra are very narrow line widths of 1 Hz or less are not uncommon so the magnetic field has to be extremely homogeneous for work at this resolution. For example, a proton spectrum recorded at 500 MHz requires variations, which, expressed as a fraction of the main magnetic field, are no more than 2×10⁻¹⁰. On its own, no superconducting magnet can produce such a homogeneous field. Thus the sample is surrounded with a set of shim coils, each of which produces a tiny magnetic field with a particular spatial profile. The current through each of these coils is adjusted until the magnetic field has the required homogeneity. Essentially, the magnetic fields produced by the shims are canceling out the small residual variations in the main magnetic field. Modern spectrometers might have up to 40 different shim coils, so adjusting them is a very complex task. Moreover, even after set on installation, it is usually necessary on a day-to-day basis to alter a few of the shims. The shims are labeled according to the magnetic field profiles they generate. The field profiles that the shims coils create are, in fact, the spherical harmonic functions, which are the angular parts of the atomic orbitals.

The probe is a cylindrical metal tube, which is inserted into the bore tube of the magnet. Small RF coil used to both excite and detect the NMR signal is held in the top of this assembly in such a way that the sample can come down from the top of the magnet and drop into the coil. Various other pieces of electronics are contained in the probe, along with some arrangements for heating or cooling the sample. The key part of the probe is the small coil used to excite and detect the magnetization. To optimize the sensitivity this coil needs to be as close as possible to the sample. Extraordinary effort has been put into the optimization of the design of this coil.

The coil forms a part of a tuned circuit consisting of the coil and a capacitor. The inductance of the coil and the capacitance of the capacitor are set such that the circuit they form is resonant at the Larmor frequency. “Tuning the probe” means adjusting the capacitor until the tuned circuit is resonant. Usually, it is also needed to “match the probe”, which involves further adjustments designed to maximize the power transfer between the probe and the transmitter and receiver. The two adjustments tend to interact rather, so tuning the probe is a tricky process. To aid it, the instrument manufacturers provide various indicators and displays so that the tuning and matching can be optimized. The tuning of the probe is particularly sensitive to changing solvent or to changing the concentration of ions in the solvent.

Thus, there remains an unresolved need in the art for improved EPR and NMR frequency resonators as well as for improved devices that utilize EPR and NMR methods, in particular EPR and NMR spectrometers.

### SUMMARY OF INVENTION

It is an object of the present invention to produce a ferroelectric single crystal consisting essentially of the potassium tantalate and the alkali metal or the group (V) metal having cubic form of perovskite crystalline structure and has reproducible physical properties.

It is also object of the present invention to provide efficient and reliable method of preparation of such ferroelectric single crystal.

It is another object of the present invention to provide a microwave resonator comprising the single crystal with predictable and consistent properties that is useful in a number of EPR and RF applications.

It is yet another object of the present invention to provide an improved EPR spectrometer.

It is still another object of the present invention to provide an improved NMR spectrometer.

Accordingly, a ferroelectric single crystal consisting essentially of the potassium tantalate and the alkali metal substituting from about 1% to about 3% of the potassium or the group (V) metal substituting in part for the tantalum, having cubic form of perovskite crystalline structure, and essentially free of impurities and defects is disclosed herein. Also, disclosed herein are methods for preparation of such ferroelectric single crystal that provide for exclusion of impurities and defects and use of such ferroelectric single crystal in resonators and various applications. As well, disclosed herein are improved EPR and NMR spectrometers.

A key aspect of the present invention involves preparation of a ferroelectric single crystal consisting essentially of the potassium tantalate and the alkali metal or the group (V) metal having cubic form of perovskite crystalline structure that is essentially free of impurities and defects by a process of a chemical reaction in a melt between the potassium precursor, the tantalum oxide and the alkali metal precursor or the group (V) metal oxide followed by contacting the melt surface with a seed crystal, lifting the seed crystal to grow a single crystal, separating the grown single crystal from the melt, and cooling the single crystal to the ambient temperature.

In general, in one aspect, the invention features a ferroelectric single crystal consisting essentially of potassium tantalate and the alkali metal substituting from about 1% to about 3% of potassium or the group (V) metal substituting in part for tantalum, said single crystal having cubic form of perovskite crystalline structure is essentially free of impurities and defects.

In general, in another aspect, the invention features a method of production a ferroelectric single crystal consisting essentially of the potassium tantalate and the alkali metal substituting from about 1% to about 3% of the potassium or the group (V) metal substituting in part for the tantalum that includes providing the potassium precursor, a tantalum foil, and the alkali metal precursor or a group (V) metal foil, burning said tantalum foil in oxygen, if said group (V) metal required, burning said group (V) metal foil in oxygen, creating a mixture of said potassium precursor, the tantalum oxide, and said alkali metal precursor or the group (V) metal oxide. The method further entails heating said mixture in a crucible to obtain a melt, contacting a lower end of a seed crystal with a surface of said melt, lifting without rotation said seed crystal to grow a single crystal, wherein said crucible is not moved, and separating the grown single crystal from said melt. The method concludes with cooling said single crystal to the ambient temperature.

In general, in yet another aspect, the invention features an EPR spectrometer comprising a ferroelectric single crystal resonator, a rectangular cavity with opposing wide sides and narrow sides, a permanent magnet with planar poles disposed parallel and in close proximity to each of the wide sides, and a radio frequency AC generator with two connecting wires. The resonator characterized by a shape substantially symmetrical relative to three mutually perpendicular planes and axes with a through hole along one of said axes. Further, the resonator positioned within the cavity between the poles with the through hole perpendicular to the narrow sides, the cavity has a sample hole coaxial with the resonator's through hole perpendicular to and through at least one of the narrow sides and two connection holes, wherein the connection holes located in close proximity to the resonator at opposite sides of the sample hole and the connecting wires inserted in said connection holes.

In general, in still another aspect, the invention features an NMR spectrometer comprising a magnet, a probe, and a ferroelectric single crystal resonator disposed in an active zone of said probe. The resonator's own resonating frequency is multiple of the Larmor frequency. The resonator characterized by a shape substantially symmetrical relative to three mutually perpendicular planes and axes with a through hole along one of said axes.

### BRIEF DESCRIPTION OF DRAWINGS

FIG. 1 depicts a schematic drawing of an apparatus for producing the single crystal.

FIG. 2 depicts an EPR spectrogram of the single crystal of potassium tantalate doped with gadolinium KTaO₃:Gd³⁺.

FIG. 2A depicts an EPR spectrogram of the single crystal of potassium tantalate—KTaO₃.

FIG. 3 depicts a schematic representation of the EPR spectrometer.

FIG. 4 depicts a part of the cavity with the resonator.

FIG. 5 depicts a schematic representation of the NMR spectrometer concept according to present invention.

### DETAILED DESCRIPTION

The present invention is directed to producing of single crystal resonators for frequencies from about 60 MHz to about 15 GHz and methods of use thereof. As used herein, the term “single crystal resonator” refers to a part fabricated from a single crystal of doped potassium tantalate. The single crystal having cubic form of perovskite crystalline structure is essentially free of impurities and defects. In one embodiment of the invention, the single crystal has K_{(0.97-0.99)}Li_{(0.03-0.01)}TaO₃ composition. In another embodiment, the single crystal has KNb_{(0 0.4)}Ta_{(1 0.6)}O₃ composition. In yet another embodiment, the single crystal with KNb_{(0 0.4)}Ta_{(1 0.6)}O₃ composition includes lithium substituting for up to 0.1% of potassium.

The method of the invention begins with providing the potassium precursor, a tantalum foil, and the alkali metal precursor or a group (V) metal foil. As used herein, the terms “potassium precursor” and “alkali metal precursor” refer to starting materials for the production of the single crystal of the invention. In one embodiment of the invention, the potassium precursor and the alkali metal precursor are respectively the potassium carbonate K₂CO₃ and the lithium carbonate Li₂CO₃. In another embodiment, the potassium precursor and the alkali metal precursor are respectively the potassium oxide K₂O and the lithium oxide Li₂O.

The method proceeds with heating the tantalum foil in oxygen to the temperature that provides for the synthesis of the tantalum oxide Ta₂O₅ for a period of time that provides for the synthesis to be completed. In one embodiment of the invention, the synthesis is carried out in a quartz tube with the oxygen flow of about 0.1 m³/h at the temperature about 900° C. for about 2 hours. In another embodiment, the synthesis is carried out in a platinum crucible with the oxygen blown in with a rate of about 0.06 m³/h at the temperature about 800° C. for about 3 hours.

The method further proceeds with heating the group (V) metal foil, particularly a niobium foil in oxygen to the temperature that provides for the synthesis of the niobium oxide Nb₂O₅ for a period of time that provides for the synthesis to be completed. Conditions for the niobium oxide synthesis are similar to the same for the tantalum oxide.

Next step of the method is creating a mixture of said potassium precursor, said tantalum oxide and said alkali metal precursor or said niobium oxide. Generally, the starting mixture created by thorough sifting, drying, weighting, and blending of the provided components. Because the mixture is hydroscopic, it is kept hermetically sealed. The components proportion in the mixture corresponds to the atomic ratio of the potassium to the tantalum with the group (V) metal is about 1.4 to 1. The proportion of the alkali metal substitute to the substituted potassium in the mixture corresponds to the atomic ratio is about 3 to 1.4 respectively.

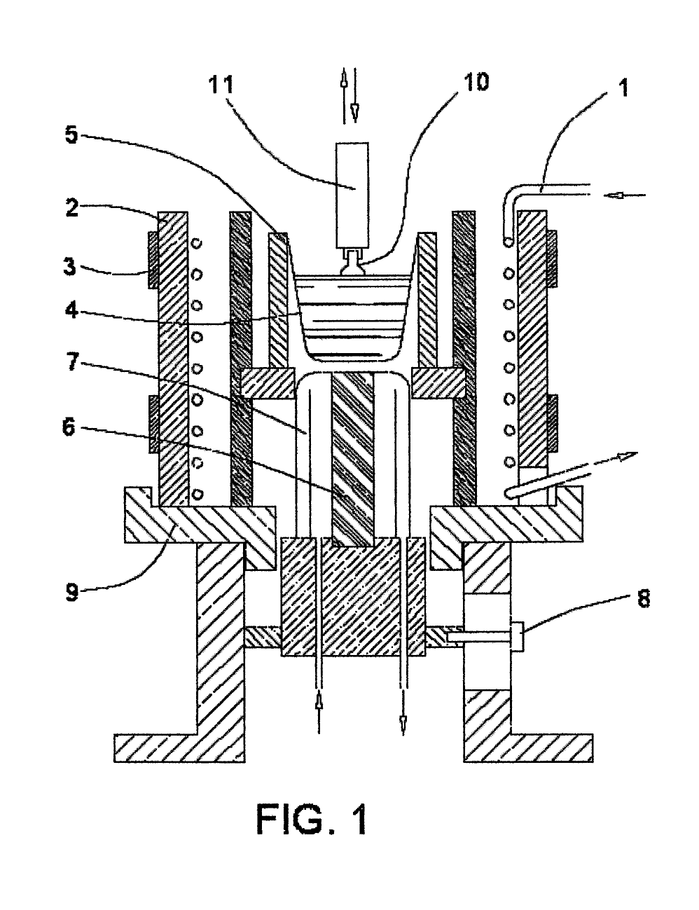

An apparatus (FIG. 1) that can be utilized to carry the method further includes a water-cooled inductor 1 surrounded by ferrite plates 2, which held together with rubber rings 3. Platinum crucible 4 is supported at its flared edge by a hollow alumina cylinder 5. A ferrite core 6 enclosed in a water-cooled quartz tube labyrinth 7 heats the crucible 4. A screw 8 fixes the ferrite core 6 relative to the crucible 4 bottom and a centering ring 9 provides radial alignment that guarantees a homogeneous thermal field. A seed crystal 10 that, usually, cut from bulk single crystal is attached with a platinum wire to an alumina rod 11, which can move up and down with the controlled speed. Typically, sides of the seed crystal 10 used for growing are natural facets and the crystal has to be free of defects because they tend to propagate into a growing single crystal.

The method continues with placing the mixture into the crucible 4 and heating it above a melting point. To decrease melting time and energy consumption, it is preferable covering initially the crucible top with a platinum lid that should have an opening for exhausting and an inspection. The melt, generally a solution of KNbO₃ and/or KTaO₃ in K₂O, is fluid, relatively non-viscous liquid. The later, coupled with the melt's ability to withstand the overcooling, provides for less stringent process conditions. In one embodiment of the invention, the method is carried in the open air. In another embodiment of the invention, the apparatus (FIG. 1) is situated in a vacuum chamber and the process is carried in vacuum.

The method proceeds with lowering the seed 10 with the rod 11 onto the melt surface and lifting it back up at the rate of 0.5 to 2 mm/h. At the same time, the melt is cooled down at the rate of 3 to 10° C./h. The seed 10 becomes a part of a growing single crystal. The rod 11 movements are strictly vertical and no rotation is introduced during the lifting. Particular rates of the lifting and the cooling depend on desired size of the single crystal. Slower lifting speed and faster cooling correspond to a greater cross section of the growing single crystal. Duration of the growing is limited by practical considerations.

The method further proceeds with separating the grown crystal from the melt. This is achieved by increasing both the lifting speed up to about 600 mm/h and the melt temperature up to about 1050° C.

Final step of the method is cooling the crystal to the ambient temperature. In one embodiment of the invention, the crystal is removed from the apparatus after it cools down to the ambient temperature naturally. In another embodiment of the invention, the crystal is cooled down at controlled rate of about 90° C./h. In yet another embodiment of the invention, the rod with the crystal is removed from the apparatus after the temperature decreases to less than 500° C. and cools further naturally.

### EXAMPLE 1

In one particular instance, the process was carried as follows. Super pure grade of the potassium carbonate K₂CO₃ and the lithium carbonate Li₂CO₃ and a tantalum foil of analytically pure grade were used. The foil was cut in about 2 mm wide pieces, placed in a quartz tube connected to an oxygen source, heated to above 850° C., and held at this temperature for 2.5 hours with the oxygen flow of about 0.1 m³/h. After the cooling, the tantalum oxide Ta₂O₅ was ground in an agate mortar, separately weighted, placed together with other components in a mass proportion of 30.94% K₂CO₃, 0.26% Li₂CO₃, and 68.8% Ta₂O₅, and thoroughly mixed. Then the mixture was placed in the apparatus (FIG. 1). The crucible was 40 mm in diameter and 50 mm high and initially covered with a platinum lid having a T shape slot. The mixture was heated to 1000±30° C. and held for 5 hours at this temperature. The synthesis of K_{0.98}Li_{0.02}TaO₃ is illustrated in a equation:
343K₂CO₃+15Li₂CO₃+250Ta₂O₅→500K_{0.98}Li_{0.02}TaO₃+98K₂O+10Li₂O+358CO₂

The seed of 1×1×7 mm size with a groove cut across two of the edges was attached to the rod with a platinum wire of 0.3 mm in diameter. The crystal was grown at the rate of about 1.2 mm/h with the melt cooled down at the rate of about 6° C./h. The size of the crystal was approximately 5 mm square and 8.5 mm long.

### EXAMPLE 2

In this instance, also, super pure grade of the potassium carbonate KCO₃ as well as tantalum and niobium foils of analytically pure grade were used. The tantalum and niobium oxides were prepared under similar to above described conditions. Mass proportion of components was 32.1% K₂CO₃, 12.2% Nb₂O₅, and 55.7% Ta₂O₅. The synthesis of KNb_{0.2}Ta_{0.8}O₃ is illustrated in a equation:
7K₂CO₃+4Ta₂O₅+Nb₂O₅→10KNb_{0.2}Ta_{0.8}O₃+2K₂O+7CO₂

It was established that, when the crucible used for the process was previously used for the example 1 process, a small amount of lithiumis present in the melt. This phenomenon was exploited here to have the crystal doped with the lithium. The crystal was grown at the rate of about 1.5 mm/h with the melt cooled down at the rate of about 8° C./h. The size of the crystal was approximately 4.5 mm square and 11 mm long. The crystal composition was K_{0.9998}Li_{0.0002}Nb_{0.2}Ta_{0.8}O₃.

The crystals produced according to present invention were studied initially to obtain measurements of temperature dependencies of the dielectric permittivity, dielectric losses and the conductivity, which are necessary to define the impurity content as well as to eliminate conductive crystals. Set up for the measuring of dielectric characteristics contains A.C. bridge—a digital L,C,R gage E7-8. Temperatures within an interval of 5.5 300 K are achieved by blowing of helium vapor from liquid helium heated by an electric furnace, which is controlled by a temperature stabilizer. Temperatures within a range of 1.2 4.2 K are achieved by pumping out of the helium vapor.

Then the electrometric method is applied. The set-up for the measuring of electric field dependence by this technique contains electrometric voltmeter VC2-16, high-voltage source and condenser with small leakage current.

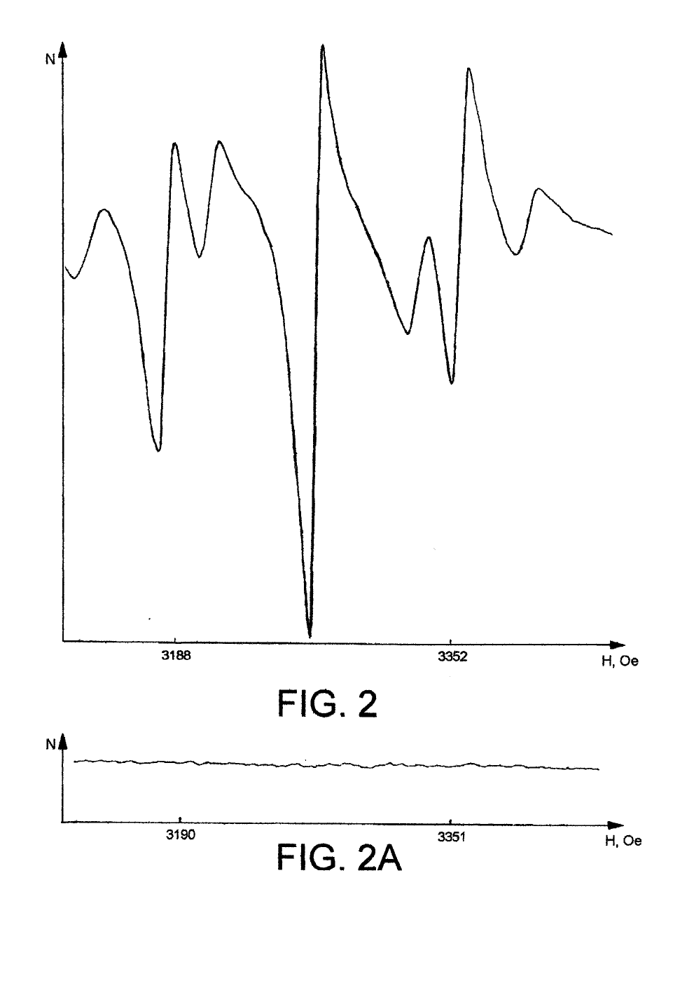

Quality of the crystals was tested by means of EPR technology. The crystals doped with either Mn²⁺ or Gd³⁺ were measured with EPR spectrometers RE-1301 and RE-1307. A line width of the dopant that narrower than 10 Oe is an evidence of a good quality and purity of crystals. The extremely small amount of defects (<10¹⁵ 1/cm³) can be detected by broadened EPR line. A graph (FIG. 2) is the EPR spectrogram of the control single crystal of present invention doped with Gd³⁺ in a magnetic field intensity axis (H) and a relative number of counts axis (N), which demonstrates a narrow Gd³⁺ line in the crystal. A graph (FIG. 2A) is the EPR spectrogram of the single crystal of present invention shows absence of detectable impurities and fewer that 10¹¹1/cm³ paramagnetic defects. This constitutes one defect for about 10⁹ to 10¹³ atoms, which means the essentially defect free crystal.

In another aspect, this invention includes a microwave resonator. The microwave resonator comprises the single crystal according to present invention. The microwave resonator can be prepared using one of the manufacturing methods used currently in the art or a combination thereof. It is important in all cases that the microwave resonator be predictable and stable at the usage temperatures. It is imperative that the microwave resonator does not react chemically with the environment during the manufacture or use of it. The single crystal in the microwave resonator can be covered with a barrier transparent to resonance frequencies or exposed. One of ordinary skill in the art will realize that other features that tasks and the environment dependent can also be used in the presently claimed invention.

Generally, the microwave resonator can be straight or curved, smooth or rough, thin or thick, solid or hollow. Although the single crystal in the microwave resonator can have any shape, preferred shapes are symmetrical relative to three mutually perpendicular planes and axes, for example, a cylinder or a hollow cylinder. The most preferable is a tetragonal prism with or without a hole along one of the axis. The preference is based on the crystal lattice, manufacturability, simplicity of calculations, and good correlation between calculations and empirical data. Methods and equations for calculating the resonator dimensions are known in the art. In one embodiment of the invention, the microwave resonator for 10 GHz (EPR) has 1.9×1.9×3.1 mm dimensions and a Ø1 mm hole through centers of square sides. In another embodiment of the invention, the microwave resonator for 300 MHz (NMR) has 5.7×5.7×8 mm dimensions and Ø1 mm hole through centers of square sides. In yet another embodiment of the invention, the microwave resonator for 300 MHz (MRI probe) with the single crystal dimensions of 5.7×5.7×8 mm and Ø0.5 mm hole has an antenna wire attached in and protruded from the hole.

In another aspect, this invention includes EPR spectrometer utilizing rectangular TE_{10δ} or cylindrical TM_{11δ} modes of a ferroelectric resonator, although it can be extended readily to TM_{mnδ} modes where m and n are any integers and to other modes as well. As is well known, EPR polarizing magnetic field is parallel to a cavity dimension that corresponds to the zero (TE₁₀) index and the magnitude of it does not affect the resonant frequency. In accordance with the present invention the ferroelectric resonator dimensions are approximately 1.9×1.9×3.1 mm. So, the cavity dimension corresponding to the zero index is made small, in the order of the corresponding dimension of the ferroelectric resonator. Optimum dimension of the cavity in the zero direction is about 2.5 mm for the spectrometer designed to operate at 10 GHz.

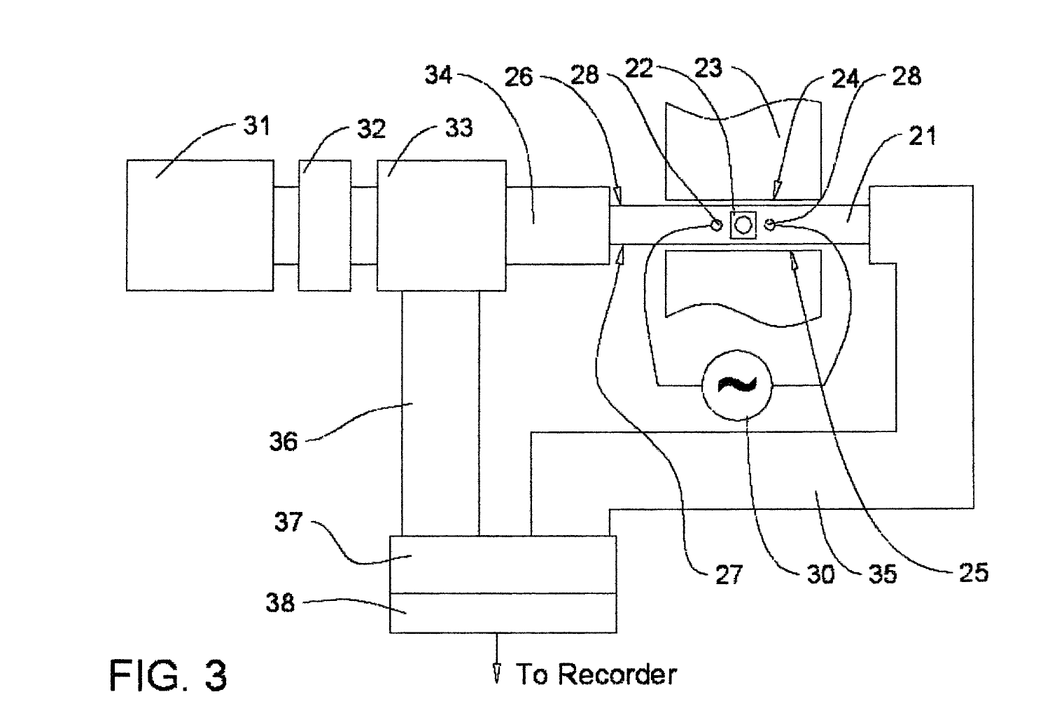

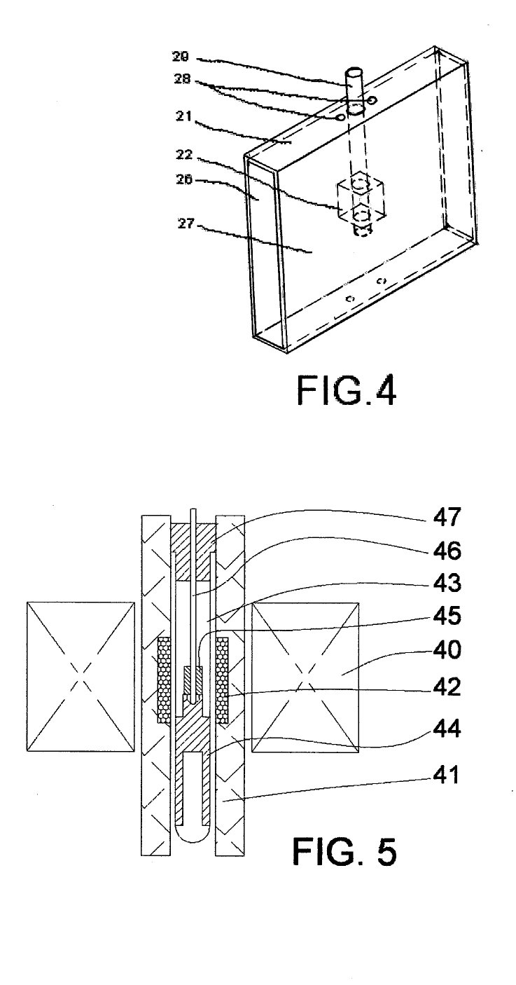

The EPR spectrometer (FIG. 3) comprises a cavity 21 with a hollow ferroelectric resonator 22, located in a gap between poles 24 and 25 of a permanent magnet 23. The poles 24 and 25 are in close proximity and parallel to wide sides correspondingly 26 and 27 of the cavity 21, which also has connection holes 28 through its narrow sides. Wires from AC generator 30, which typically has a frequency on the order of 100 KHz, are inserted trough the holes 28. A waveguide 34 connects the cavity 21 to a microwave generator 31 through a valve 32 and a directed branching 33. The cavity 21 and the branching 33 are connected through waveguides correspondingly 35 and 36 to a diode detector 38 through a balance mixer 37. A sample holder 29 (FIG. 4) is inserted in the resonator 22 through the corresponding cavity hole.

The holder 29 may be either a capillary containing a liquid sample or a rod with a glued on solid sample to be analyzed by EPR spectroscopy techniques. Microwave energy is coupled to the cavity 21 and the resonator 22 from the microwave generator 31 through the valve 32, the branching 33, and the waveguide 34. For purpose of this application, the microwave generator 31 having a noise spectrum equal to or comparable to a Gunn oscillator is used. In one of embodiments of the invention, a Gunn oscillator having a frequency of 9.4 GHz was employed to excite the cylindrical ferroelectric resonator to the TM_{11δ} mode. The ferroelectric resonator had the diameter of 1.9 mm and the height 3 mm with a hole Ø0.9 mm. The flux from a relatively strong magnetic field that includes DC component of the permanent magnet 23 on which small AC component is imposed extends in the cavity 21 and in the resonator 22. Because of the small gap between the poles 24 and 25, the magnet's 15 size and weight are reduced. The AC magnetic field component is provided by the wires from the AC generator 30 inserted in the holes 28. The energy from the resonator 22 and the cavity 21 through the waveguide 35, as well as the energy directly from the generator 31 through the waveguide 36 is coupled to the balance mixer 37 and detected by diode detector 38. A signal derived from the detector 38 is fed to a suitable output device, such as a chart recorder. As is well known, when resonance occurs in the sample, the energy from the resonator provides a finite output from the diode detector 38.

It has been found that the sensitivity of the EPR spectrometer of this invention is, typically, 50 times higher than that obtained from high Q cavities of conventional design. This result can be understood when one recognizes that the sensitivity is proportional to the product of a filling factor (η) and the cavity Q. Furthermore, η is proportional to ε of the resonator and inversely proportional to ε of the cavity. Moreover, if the sample dimensions are held constant, it is apparent that η is inversely proportional to the cavity dimension corresponding to the zero (TE₁₀) index. Thus the product ηQ is increased greatly.

The homogeneity of the magnetic field for a fixed magnet pole piece diameter and fixed field improves as the magnet gap is decreased and the area of the required homogeneity becomes smaller. For a fixed magnetic field the required number of ampere turns decreases as the gap decreases. Accordingly, the magnet size required in order to avoid magnetic saturation of the iron is smaller for a smaller number of the ampere turns. An approximate rule of thumb is that the weight of a magnet of constant pole piece diameter and the constant magnetic field intensity varies in proportion to the third power of the magnet gap. Generally, it is true for a permanent magnet also. According to present invention, the gap between the poles 24 and 25 is approximately 3 mm with a resulting weight of the permanent magnet 23 of approximately 0.6 kg. In conventional prior art even in rectangular configurations, the gap is greater than 17 mm requiring a magnet weight in excess of 100 kg.

Thus, according to present invention, the EPR spectrometer affords, on orders of magnitude, an increase in sensitivity, a decrease of the incident microwave power required, a reduction of the weight and the size. In other words, the present invention provides for a portable EPR spectrometer with capabilities of high-end research spectrometers.

In another aspect, this invention includes NMR spectrometer utilizing a ferroelectric resonator. The NMR spectrometer (FIG. 5) comprises a hollow magnet 40 generating a static magnetic field, a tubular probe 41 with a RF magnetic pulse transmitter/receiver 42 displaced in the magnet 40 hole, a holder 43, and a ferroelectric single crystal resonator 45. A cap 47 positions the holder 43 and a sample 46 within the probe 41. A support 44 situates the resonator 45 and defines the sample 46 placement within the resonator 45. The probe 41, the holder 43, the resonator 45, and, accordingly, the sample 46 are coaxial with the static magnetic field. Furthermore, the RF magnetic pulse transmitter/receiver 42 and the resonator 45 are disposed in the most homogeneous zone of the static magnetic field.

In one embodiment of the present invention the holder 43 with the support 44, the resonator 45, the sample 46, and the cap 47 is used as an insert with conventional NMR spectrometer. In this embodiment an RF coil of the spectrometer serves as the RF magnetic pulse transmitter/receiver 42. In a particular instant, the resonator 45 was a single crystal of KTaO₃ with dimensions approximately 6×6×7 mm and had a hole of about 1 mm in diameter along a 7 mm axis. The resonator 45 own resonant frequency was 1200 MHz and the RF coil resonant frequency and, accordingly, frequency of the spectrometer was 400 MHz. The liquid sample 46 was placed in a capillary of 1 mm in diameter. The insert presence increased signal-to-noise ratio in hydrogen NMR spectra in about 10 times.

In another instant, the resonator 45 having the resonant frequency of 9000 MHz was used with the spectrometer working at the frequency of 300 MHz. This combination yielded only doubling of the signal-to-noise ratio. According to the present invention, the resonator 45 having own resonant frequency, which is multiple of frequency of the NMR spectrometer, increases sensitivity of the spectrometer. The greatest increase of the signal-to-noise ratio occurs when the resonator 45 own resonant frequency is equal to the frequency of the NMR spectrometer. The sensitivity, in this case, is expected to be up to 50 times higher.

In another embodiment of the present invention, the NMR spectrometer has the magnet 40 that is a superconducting magnet, the holder 43 that is a part of the probe 41, the RF magnetic pulse transmitter/receiver 42 that is a loop, and the resonator 45 that is capable of generating the pulse magnetic field perpendicular to the static magnetic field. As is well known, in general, in NMR spectrometers the magnetic pulse field generated by the RF coil is perpendicular to a static magnetic field. Methods to calculate parameters of the resonator 45 so the magnetic pulse field is perpendicular to a static magnetic field are, also, well known in the art. The spectrometer described is capable of utilizing higher frequency than spectrometers with RF coils.

In yet another embodiment of the present invention, the simplified NMR spectrometer has the magnet 40 that is permanent magnet with a relatively small center hole (20 to 30 mm), the holder 43 that is a part of the probe 41, the RF magnetic pulse transmitter/receiver 42 that is a loop, and the resonator 45 that is capable of generating the pulse magnetic field perpendicular to the static magnetic field.

Thus, according to present invention, the NMR spectrometer affords either radical improvement of a spectrogram quality by increasing sensitivity and the working frequency or a decrease of the power required, a reduction of the weight and the size.

Although the description above contains much specificity, it should not be construed as limiting the scope of the invention but as merely providing illustrations of some of the presently preferred embodiments of this invention. Thus the scope of the invention should be determined by the appended claims and their legal equivalents, rather than by the examples given. It will be apparent to those skilled in the art that various modifications and variations can be made to the above-described structure and methodology without departing from the scope or spirit of the invention.

1. A ferroelectric single crystal, consisting essentially of:
the potassium tantalate; and
the alkali metal or the group (V) metal;
said alkali metal substitutes for from about 1% to about 3% of the potassium, said group (V) metal substitutes for a part of the tantalum; and
said single crystal having cubic form of perovskite crystalline structure is essentially free of impurities and defects.

2. The single crystal according to claim 1, wherein said alkali metal is lithium, whereby forming a K_{(0.97 0.99)}Li_{(0.03 0.01)}TaO₃ composition.

3. The single crystal according to claim 1, wherein said group (V) metal is niobium, said niobium substituting of up to about 40% of tantalum, whereby forming a KNb_{(0 0.4)}Ta_{(1 0.6)}O₃ composition.

4. The single crystal according to claim 3, consisting of lithium substituting for up to 0.1% of potassium.

5. A method of production a ferroelectric single crystal consisting essentially of the potassium tantalate and the alkali metal substituting from about 1% to about 3% of the potassium or the group (V) metal substituting in part for the tantalum, said single crystal having cubic form of perovskite crystalline structure is essentially free of impurities and defects comprising the steps of:
(a) providing the potassium precursor, a tantalum foil, and the alkali metal precursor or a group (V) metal foil;
(b) heating said tantalum foil in the oxygen, whereby synthesizing the tantalum oxide;
(c) if said group (V) metal required, heating said group (V) metal foil in the oxygen whereby synthesizing the group (V) metal oxide;
(d) creating a mixture of said potassium precursor, said tantalum oxide, and said alkali metal precursor or said group (V) metal oxide;
(e) heating said mixture in a crucible to obtain a melt;
(f) contacting a lower end of a seed crystal with a surface of said melt;
(g) lifting without rotation said seed crystal to grow a single crystal, wherein said crucible is not moved;
(h) separating the grown single crystal from said melt; and
(i) cooling said single crystal to the ambient temperature;

6. The method according to claim 5, wherein said potassium precursor is the potassium carbonate K₂CO₃.

7. The method according to claim 5, wherein said alkali metal precursor is the lithium carbonate Li₂CO₃.

8. The method according to claim 5, wherein said group (V) metal foil is a niobium foil.

9. A microwave resonator comprising the single crystal according to claim 1.

10. The microwave resonator according to claim 9, wherein, for frequencies from about 7 GHz to about 15 GHz, said single crystal has said K_{(0.97-0.99)}Li_{(0.03 0.01)}TaO₃ composition.

11. The microwave resonator according to claim 10, characterized by a shape substantially symmetrical relative to three mutually perpendicular planes and axes with a through hole along the longest of said axes.

12. The microwave resonator according to claim 9, wherein, for frequencies from about 60 MHz to about 10 GHz, said single crystal has said KNb_{(0 0.4)}Ta_{(1 0.6)}O₃ composition.

13. The microwave resonator according to claim 12, comprising biologically inert and a resonant frequency transparent coating and a holder for attaching said microwave resonator to a catheter.

14. The microwave resonator according to claim 12, characterized by a shape substantially symmetrical relative to three mutually perpendicular planes and axes with a through hole along one of said axes.

15. An EPR spectrometer with a rectangular cavity having opposing wide sides and narrow sides, a permanent magnet with planar poles disposed parallel and in close proximity to each of said wide sides, and a radio frequency AC generator with two connecting wires, comprising:
a ferroelectric single crystal resonator;
a through hole in said ferroelectric single crystal resonator;
a sample hole; and
two connection holes;
said sample hole and said connection holes are perpendicular to and through at least one of said narrow sides of said rectangular cavity, said ferroelectric single crystal resonator positioned within said rectangular cavity between said planar poles with said through hole perpendicular to said narrow sides, said sample hole is coaxial with said through hole, said connection holes are located in close proximity to said ferroelectric single crystal resonator at opposite sides of said sample hole, and said connecting wires are inserted in said connection holes.

16. The EPR spectrometer according to claim 15, wherein said ferroelectric single crystal resonator is a ferroelectric single crystal composed of K_{(0.97 0.99)}Li_{(0.03 0.01)}TaO₃, said ferroelectric single crystal having cubic form of perovskite crystalline structure is essentially free of impurities and defects.

17. The EPR spectrometer according to claim 16, wherein said ferroelectric single crystal resonator characterized by a shape substantially symmetrical relative to three mutually perpendicular planes and axes with the through hole along one of said axes.

18. A NMR spectrometer comprising:
a magnet forming a static homogeneous magnetic field;
a probe with means for transmitting a radio frequency magnetic pulse and detecting NMR signal;
a ferroelectric single crystal resonator; and
a through hole in said ferroelectric single crystal resonator.

19. The NMR spectrometer according to claim 18, wherein a resonant frequency of said ferroelectric single crystal resonator is effectively a multiple of the NMR spectrometer frequency.

20. The NMR spectrometer according to claim 18, wherein said probe, said ferroelectric single crystal resonator, and said hole are substantially coaxial with said static homogeneous magnetic field axis.

21. The NMR spectrometer according to claim 18, wherein said ferroelectric single crystal resonator characterized by a shape substantially symmetrical relative to three mutually perpendicular planes and axes with the through hole along one of said axes.
